(19) United States
(12) Patent Application Publication
(10) Pub. No.: US 2024/0213737 A1
(43) Pub. Date: Jun. 27, 2024

(54) LASER

(71) Applicant: HISENSE LASER DISPLAY CO., LTD., Shandong (CN)

(72) Inventors: Zinan Zhou, Shandong (CN); Youliang Tian, Shandong (CN); Xin Zhang, Shandong (CN); Yao Lu, Shandong (CN); Wei Li, Shandong (CN); Xianrong Liu, Shandong (CN); Xinghe Xue, Shandong (CN); Xiaoqiang Gu, Shandong (CN)

(21) Appl. No.: 18/595,871

(22) Filed: Mar. 5, 2024

Related U.S. Application Data
(63) Continuation of application No. PCT/CN2022/117390, filed on Sep. 6, 2022.

(30) Foreign Application Priority Data
Sep. 6, 2021 (CN) 202111038583.3
Sep. 7, 2021 (CN) 202111045935.8
Dec. 31, 2021 (CN) 202111672608.5
Dec. 31, 2021 (CN) 202123444019.X

(51) Int. Cl. H01S 5/02253; G02B 27/30; H01S 5/40

(52) U.S. Cl. CPC H01S 5/02253; G02B 27/30; H01S 5/4025

(57) ABSTRACT

A laser is provided. The laser includes a base plate, a frame, a plurality of light-emitting subassemblies, a plurality of first conductive structures and a second conductive structure. The frame is disposed on the base plate and is configured to form an accommodation space with the base plate, the plurality of light-emitting subassemblies are disposed on the base plate and in the accommodation space, the plurality of first conductive structures are spaced apart at an end of the frame proximal to the base plate, wherein each of the first conductive structures includes a substrate insulated from the base plate and a conductive layer disposed on a surface of the substrate distal to the base plate; and the second conductive structure has one end electrically connected to the conductive layer and another end connected to at least one of the plurality of light-emitting subassemblies.

### CROSS-REFERENCE TO RELATED APPLICATIONS

This application is a continuation application of international application No. PCT/CN2022/117390, filed on Sep. 6, 2022, which claims priority to Chinese Patent Application No. 202111672608.5 filed on Dec. 31, 2021, Chinese Patent Application No. 202111038583.3 filed on Sep. 6, 2021, Chinese Patent Application No. 202111045935.8 filed on Sep. 7, 2021, and Chinese Patent Application No. 202123444019.X filed on Dec. 31, 2021, which are incorporated herein by reference in their entireties.

### TECHNICAL FIELD

The present disclosure relates to the field of optoelectronic technologies, and in particular, to a laser.

### BACKGROUND

With the development of the optoelectronic technology, lasers are widely used. For example, lasers are used as light sources for laser projection devices or laser televisions. Therefore, the demand for miniaturization and reliability of the lasers is also increasing.

### SUMMARY

According to some embodiments of the present disclosure, a laser is provided. The laser includes a base plate, a frame, a plurality of light-emitting subassemblies, a plurality of first conductive structures, and a second conductive structure. The frame is disposed on the base plate and is configured to form an accommodation space with the base plate, the plurality of light-emitting subassemblies are disposed on the base plate and in the accommodation space, the plurality of first conductive structures are spaced apart at an end of the frame proximal to the base plate, wherein each of the first conductive structures includes a substrate insulated from the base plate and a conductive layer disposed on a surface of the substrate distal to the base plate; and the second conductive structure has one end electrically connected to the conductive layer and another end connected to at least one of the plurality of light-emitting subassemblies.

### BRIEF DESCRIPTION OF THE DRAWINGS

FIG. 1 is a structural diagram of a laser according to the related art;

FIG. 2 is a structural diagram of a laser according to some embodiments of the present disclosure;

FIG. 3 is an exploded structural diagram of a laser according to some embodiments of the present disclosure;

FIG. 4 is a structural diagram of a laser according to some embodiments of the present disclosure;

FIG. 5 is a structural diagram of a laser according to some embodiments of the present disclosure;

FIG. 6 is a structural diagram of another laser according to some embodiments of the present disclosure;

FIG. 7 is a structural diagram of a laser according to the related art;

FIG. 8 is a structural diagram of yet another laser according to some embodiments of the present disclosure;

FIG. 9 is a structural diagram of another laser according to some embodiments of the present disclosure;

FIG. 10 is a structural diagram of another laser according to some embodiments of the present disclosure;

FIG. 11 is a structural diagram of yet another laser according to some embodiments of the present disclosure;

FIG. 12 is a structural diagram of still another laser according to some embodiments of the present disclosure;

FIG. 13 is a structural diagram of a collimating lens according to some embodiments of the present disclosure;

FIG. 14 is a structural diagram of another collimating lens according to some embodiments of the present disclosure;

FIG. 15 is a structural diagram of still another collimating lens according to some embodiments of the present disclosure;

FIG. 16 is a structural diagram of yet another collimating lens according to some embodiments of the present disclosure;

FIG. 17 is a structural diagram of a collimating lens according to some other embodiments of the present disclosure;

FIG. 18 is a structural diagram of another collimating lens according to some other embodiments of the present disclosure;

FIG. 19 is a structural diagram of a collimating lens group according to some embodiments of the present disclosure;

FIG. 20 is a structural diagram of another collimating lens group according to some embodiments of the present disclosure;

FIG. 21 is a structural diagram of still another collimating lens group according to some embodiments of the present disclosure;

FIG. 22 is a structural diagram of yet another collimating lens group according to some embodiments of the present disclosure;

FIG. 23 is a structural diagram of still another laser according to some embodiments of the present disclosure;

FIG. 24 is a structural diagram of a section of the laser in FIG. 23 in B-B′;

FIG. 25 is a structural diagram of another laser according to the related art;

FIG. 26 is a structural diagram of yet another laser according to some embodiments of the present disclosure;

FIG. 27 is a structural diagram of a section of the laser shown in FIG. 26 in D-D′;

FIG. 28 is a structural diagram of yet another laser according to some embodiments of the present disclosure;

FIG. 29 is a structural diagram of yet another laser according to some embodiments of the present disclosure;

FIG. 30 is a structural diagram of yet another laser according to some embodiments of the present disclosure; and

FIG. 31 is a structural diagram of yet another laser according to some embodiments of the present disclosure.

### DETAILED DESCRIPTION

The technical solutions in some embodiments of the present disclosure are described below clearly and completely with reference to the accompanying drawings. Apparently, the described embodiments are merely some rather than all of the embodiments of the present disclosure. All other embodiments obtained by those of ordinary skill in the art based on the embodiments provided in the present disclosure shall fall within the protection scope of the present disclosure.

FIG. 2 to FIG. 6 show a laser according to some embodiments of the present disclosure. As shown in FIG. 2 to FIG. 4, a laser 10 includes a package 120, a plurality of first conductive structures 103, a plurality of light-emitting subassemblies 130, and a second conductive structure 105. The package 120 includes a base plate 101 and a frame 102. A side of the package 120 is provided with an opening. An opening of the frame 102 distal to the base plate 101 is the opening of the shell 120. The frame 102 and the plurality of light-emitting subassemblies 130 are disposed on the base plate 101. The frame 102 is annular. The base plate 101 and the frame 102 enclose an accommodation space S. The light-emitting subassemblies 130 are disposed in the accommodation space S. The frame 102 includes a plurality of notches K that are spaced apart at the end of the frame 102 distal to the base plate 101. The plurality of notches K correspond to the plurality of first conductive structures 103. The shape of the first conductive structure 103 matches the shape of the corresponding notch K. The first conductive structure 103 fills the corresponding notch K.

The base plate 101 and the frame 102 in the package 120 are an integral structure, or are separate structures and welded together to form the package 120. In some embodiments, the package 120 is made of copper, such as oxygen-free copper. Due to the high thermal conductivity of copper, heat generated by the light-emitting subassembly 130 during operation can be quickly conducted through the package 120, and then dissipated quickly, to avoid damage to the light-emitting subassembly 130 caused by heat accumulation. The package may alternatively be made of one or more of aluminum, aluminum nitride, and silicon carbide.

In some embodiments, the plurality of first conductive structures 103 are made of ceramic, the frame 102 is made of metal. The plurality of notches K are spaced apart at the end of the frame proximal to the base plate 101, and the plurality of first conductive structures 103 are arranged in the plurality of notches K in a one-to-one correspondence.

In some embodiments, as shown in FIG. 3, the light-emitting subassembly 130 includes a light-emitting chip 104. The first conductive structure 103 includes a substrate 1031 and a conductive layer 1032 disposed on the substrate 1031. The substrate 1031 includes a first portion B1, a third portion B3, and a second portion B2 that are connected in sequence. The third portion B3 is disposed between the first portion B1 and the second portion B2, and the third portion B3 is disposed in the notch K. The conductive layer 1032 includes a first conductive layer D1. The third portion B3 of the substrate 1031 is covered by the frame 102. The first conductive layer D1 is disposed on a side of the first portion B1 distal to the base plate 101. The first conductive layer D1 is connected to the light-emitting chip 104 through the second conductive structure 105.

The substrate 1031 serves as a carrier for the first conductive layer D1. The substrate 1031 can isolate the first conductive layer D1 from another component in the laser 10, to prevent the another component in the laser 10 from affecting a conductive effect of the first conductive layer D1. For example, the substrate 1031 isolates the first conductive layer D1 from the base plate 101 and isolates the first conductive layer D1 from the frame 102. In some embodiments, the first conductive structure 103 is fastened in the corresponding notch K through brazing. In this case, the first portion B1 is located in the accommodation space S, and the second portion B2 is located outside the accommodation space S. For example, the third portion B3 of the first conductive structure 103 is aligned and snapped into the corresponding notch K. Solder is disposed between the first conductive structure 103 and the corresponding notch K. Then, the frame 102 with the first conductive structures 103 snapped into the notches K is placed in a high-temperature furnace for sintering such that the solder melts, to fasten the first conductive structures 103 in the corresponding notches K and ensure sealing at connections between the first conductive structures 103 and the corresponding notches K. For example, the first conductive layer D1 is disposed on the substrate 1031 before the first conductive structures 103 and the frame 102 are soldered. In this case, the first conductive layer D1 and the substrate 1031 are an integral structure. Alternatively, the first conductive layer D1 is disposed on the substrate 1031 after the substrate 1031 is fastened to the frame 102. In this case, the first conductive layer D1 and the substrate 1031 are not an integral structure.

After all first conductive structures 103 are fastened in the corresponding notches K, the integral structure composed of the frame 102 and the first conductive structures 103 is welded to the base plate 101. A side of the integral structure on which the first conductive structures 103 are located is in contact with the base plate 101. The base plate 101, the frame 102, and the plurality of first conductive structures 103 enclose the accommodation space S such that the light-emitting subassemblies 130 can be fastened in the accommodation space S. Then, the second conductive structure 105 is disposed between the first conductive layer D1 in the first conductive structure 103 and the light-emitting chip 104 proximal to the first conductive structure 103, and between light-emitting chips 104 to be connected in series, to electrically connect the first conductive structures 103 and the light-emitting chips 104.

In some embodiments, the second conductive structure 105 is a wire, and the second conductive structure 105 is fastened on the first conductive layer D1 and the light-emitting chip 104 through ball bonding. When the second conductive structure 105 is welded through ball bonding, an end of the second conductive structure 105 is melted through a second conductive structure bonding device and then pressed against an object to be connected. Then, the second conductive structure bonding device applies an ultrasonic wave to fasten the second conductive structure 105 to the object to be connected. For example, the second conductive structure 105 is a gold wire. A process of fastening the second conductive structure 105 to the first conductive structure 103 is referred to as a gold wire bonding process. The notch K is provided on a side of the frame 102 proximal to the base plate 101. The first conductive structure 103 is fastened in the notch K. Therefore, the first conductive structure 103 can be in contact with the base plate 101 to be supported by the base plate 101. In this way, the first conductive structure 103 has a high ability to withstand pressure during wire bonding. There is a low probability that the first conductive structure 103 is damaged due to pressure applied by the wire bonding device and high welding firmness between the second conductive structure 105 and the first conductive layer D1, which improves the success rate of wire bonding and the fastening effect of the second conductive structure 105, thereby improving a manufacturing yield of the laser.

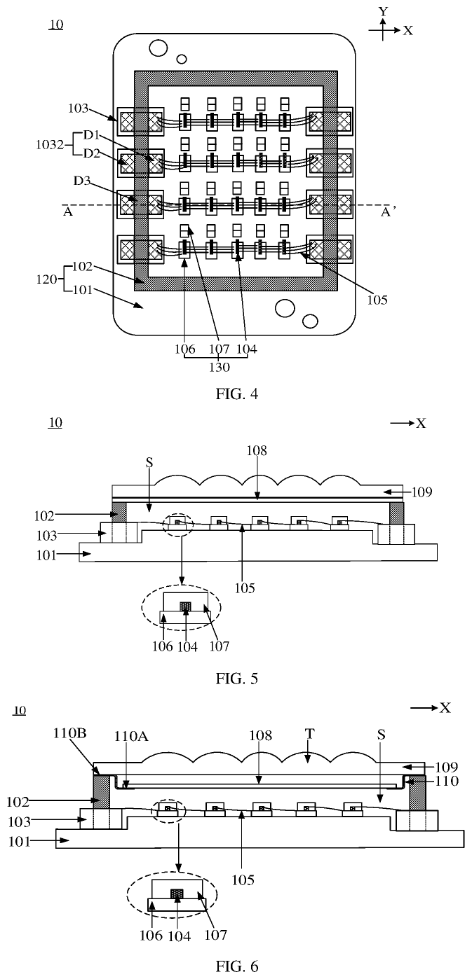

In some embodiments, components of the laser 10 that need to be connected are electrically connected through a plurality of second conductive structures 105 to ensure connection reliability between two components that need to be electrically connected and reduce a sheet resistance on the second conductive structures 105. As shown in FIG. 4, the first conductive layer D1 is connected to the light-emitting chip 104, and adjacent light-emitting chips 104 are connected to each other through a plurality of second conductive structures 105 (e.g. a plurality of wires). FIG. 2 shows only one second conductive structure 105 (e.g. one wire) as an example.

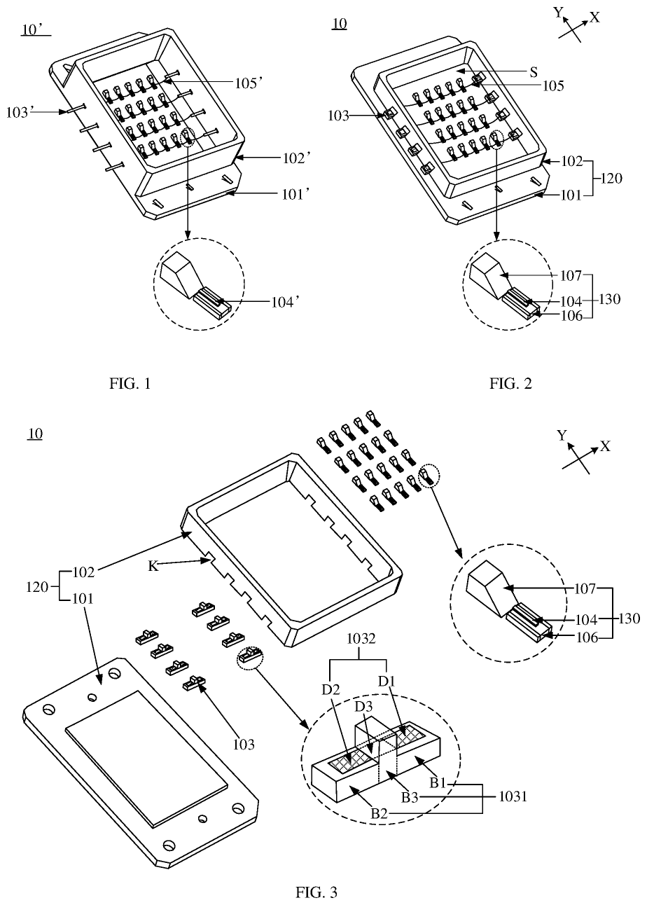

In the related art, as shown in FIG. 1, to avoid the impact of a bottom plate 101′ on the conductive performance of a conductive pin 103′, it is necessary to keep a large safe distance between the conductive pin 103′ and the bottom plate 101′. Therefore, a frame 102′ in a laser 10′ needs to have a large height, which is not conducive to the miniaturization of the laser. In addition, because the conductive pin 103′ is suspended, the conductive pin 103′ has a low ability to withstand pressure when pressure is applied to the conductive pin 103′ through the wire bonding device to fasten a wire 105′ (the wire 105′ connects a light-emitting chip 104′ and an external power supply) in a process of manufacturing the laser 10′. The conductive pin 103′ is prone to damage, resulting in poor reliability of the laser 10′. However, in the laser provided in some embodiments of the present disclosure, because the first conductive layer D1 can be insulated from the base plate 101 through the substrate 1031, there is no need to set a safe distance between the first conductive layer D1 and the base plate 101. In addition, the first conductive structure 103 is located in the notch K on the side of the frame 102 proximal to the base plate 101 such that a distance between the first conductive layer D1 and the base plate 101 is small. Therefore, the height of the frame 102 and the thickness of the laser can be small, which is conducive to the miniaturization of the laser 10.

A structure of the first conductive structure 103 in the laser 10 is described below with reference to the accompanying drawings.

In some embodiments, referring to FIG. 2 to FIG. 4, an arrangement direction of the first portion B1, the second portion B2, and the third portion B3 is parallel to an X direction. The first portion B1 is located in the accommodation space S. The second portion B2 is located outside the accommodation space S. The third portion B3 fills the notch K of the frame 102. For example, a dimension of the third portion B3 in the X direction is greater than or equal to the wall thickness of the frame 102, to ensure that the third portion B3 has a good filling effect on the notch K, thereby ensuring airtightness at the notch K.

For example, the conductive layer 1032 further includes a second conductive layer D2. The second conductive layer D2 is disposed on the surface of the second portion B2 distal to the base plate 101. The first conductive structure 103 includes a connection layer D3. The connection layer D3 is embedded inside the third portion B3. The first conductive layer D1 and the second conductive layer D2 are connected, for example, through the connection layer D3. The second conductive layer D2 is connected to an external power supply. A current generated by the external power supply is transmitted to the light-emitting chip 104 through the second conductive layer D2, the connection layer D3 in the first conductive structure 103, and the first conductive layer D1 in sequence.

For example, the surface of the first portion B1 distal to the base plate 101 is flush with the surface of the second portion B2 distal to the base plate 101. This is conducive to a connection between the first conductive layer D1 and the second conductive layer D2. Alternatively, there is a height difference between the surface of the first portion B1 distal to the base plate 101 and the surface of the second portion B2 distal to the base plate 101.

For example, the first conductive layer D1 completely covers or partially the surface of the first portion B1 distal to the base plate 101. The second conductive layer D2 completely or partially covers the surface of the second portion B2 distal to the base plate 101. An example in which the first conductive layer D1 partially covers the surface of the first portion B1 distal to the base plate 101 and the second conductive layer D2 partially covers the surface of the second portion B2 distal to the base plate 101 is used for description in some embodiments of the present disclosure. This can reduce the risk that the frame 102 is in contact with the first conductive layer D1 and the second conductive layer D2.

In some embodiments, the third portion B3 of the first conductive structure 103 protrudes relative to the first portion B1 and the second portion B2 in a direction (for example, a Y direction in the figure) away from the base plate 101. The protrusion of the third portion B3 can ensure that both the first conductive layer D1 and the second conductive layer D2 are spaced apart from the frame 102, to prevent the frame 102 from affecting the conductive effect of the first conductive layer D1 and the second conductive layer D2.

In some embodiments, the surface of the first conductive structure 103 proximal to the base plate 101 is flush with an annular surface of the frame 102 proximal to the base plate 101. In this way, after the first conductive structures 103 are fastened in the notches K, it can be ensured that the surface of the integral structure composed of the frame 102 and the first conductive structures 103 proximal to the base plate 101 is flat such that an effect of welding the integral structure on the base plate 101 is good, a risk that there is a crack at a welding position is low, and good airtightness of the laser 10 can be ensured.

An example in which surfaces of the first portion B1, the second portion B2, and the third portion B3 proximal to the base plate 101 are flush with each other and with the annular surface of the frame 102 close to the base plate 101 is used in some embodiments of the present disclosure. Alternatively, only the surface of the third portion B3 proximal to the base plate 101 is flush with the annular surface of the frame 102 proximal to the base plate 101, and the surface of at least one of the first portion B1 and the second portion B2 proximal to the base plate 101 is spaced apart from the base plate 101. This can increase a safe distance between the first conductive layer D1 and the base plate 101 and a safe distance between the second conductive layer D2 and the base plate 101.

An example in which the base plate 101 and the frame 102 in the package 120 are two separate structures that need to be assembled is used in the foregoing description. Alternatively, the base plate 101 and the frame 102 are an integral structure. This can avoid a wrinkle on the base plate 101 due to different coefficients of thermal expansion of the base plate 101 and the frame 102 when the base plate 101 and the frame 102 are welded at high temperature such that flatness of the base plate 101 and reliability of disposing the light-emitting subassemblies 130 on the base plate 101 can be ensured, to ensure that light emitted by the light-emitting chip 104 is emergent at a predetermined light-emitting angle and improve a light-emitting effect of the laser 10.

For example, the plurality of notches K are evenly distributed on two opposite sidewalls of the frame 102, such as two opposite sidewalls of the frame 102 in the X direction. Correspondingly, the plurality of first conductive structures 103 are also distributed on the two opposite sidewalls. The conductive layer 1032 in the first conductive structure 103 disposed on one of the two sidewalls is configured to connect to an anode of the external power supply. The conductive layer 1032 in the first conductive structure 103 disposed on the other sidewall is configured to connect to a cathode of the external power supply. For example, a plurality of light-emitting chips 104 in the laser 10 are arranged in a plurality of rows and a plurality of columns. The row direction of the light-emitting chips 104 is the X direction, and The column direction is the Y direction. The light-emitting chips 104 in each row are connected in series. Each row of light-emitting chips 104 has two ends respectively provided with two first conductive structures 103 and is connected to the anode and the cathode of the external power supply through the two first conductive structures 103, respectively.

In some embodiments, quantities of first conductive layers D1 and second conductive layers D2 are related to an arrangement manner of the light-emitting chips 104 in the laser and a circuit connection manner. For example, light-emitting chips 104 of the same type in the laser 10 are configured to emit laser light of the same color. Light-emitting chips 104 of different types are configured to emit laser light of different colors. Light-emitting chips 104 of each type are connected in series and do not share the first conductive layer D1 or the second conductive layer D2.

For example, the laser 10 is a multicolor laser having a plurality of light-emitting chips configured to emit laser light of different colors. For example, the laser 10 includes three types of light-emitting chips configured to emit red laser light, green laser light, and blue laser light, respectively. In this case, laser 10 includes six first conductive structures. Three of the six first conductive structures serve as anode pins and the other three as cathode pins. Each type of light-emitting chip 104 is connected to one anode pin and one cathode pin. Alternatively, different types of light-emitting chips 104 share the first conductive layer D1 and the second conductive layer D2.

A plurality of light-emitting chips 104 in the same type of light-emitting chips 104 are connected in series. For example, the laser 10 is a monochromatic laser having a plurality of light-emitting chips 104 configured to emit laser light of the same color. In this case, all light-emitting chips 104 in the laser 10 are connected in series, and the laser 10 includes only two first conductive structures 103. In this way, only one switch is needed to control on/off of the plurality of light-emitting chips 104. In addition, because currents are equal at all positions of a series circuit of the plurality of light-emitting chips 104, the requirement for an input current is low and the threshold current of each light-emitting chip 104 is easily reached, which facilitates light emission of the light-emitting chips 104.

In some embodiments, referring to FIG. 2 to FIG. 4, the laser 10 includes a plurality of heat sinks 106 and a plurality of reflecting prisms 107. The plurality of reflecting prisms 107 and the plurality of heat sinks 106 correspond to the plurality of light-emitting chips 104. The heat sinks 106 are disposed on the base plate 101 in the package 120. The light-emitting chips 104 are disposed on the corresponding heat sinks 106. The heat sinks 106 are configured to assist the corresponding light-emitting chips 104 in dissipating heat. The material of the heat sink 106 includes ceramic. The reflecting prism 107 is disposed on a light-emitting side of the corresponding light-emitting chip 104. The light-emitting chip 104 emits laser light to the corresponding reflecting prism 107. The reflecting prism 107 reflects the laser light in the direction away from the base plate 101.

FIG. 5 is a structural diagram of a section of the laser 10 shown in FIG. 4 in A-A′. In some embodiments, as shown in FIG. 5, the laser 10 further includes a light-transmitting layer 108. The light-transmitting layer 108 is a plate-like structure, is located on a side of the frame 102 distal to the base plate 101, and is configured to seal the accommodation space S enclosed by the frame 102 and the base plate 101. For example, the light-transmitting layer is made of glass, or another light-transmitting and reliable material, such as a resin material.

In some embodiments, as shown in FIG. 6, the laser 10 further includes a cover plate 110. The cover plate 110 includes an inner edge region 110A and an outer edge region 110B. The outer edge region 110B is fastened to a surface of the frame 102 distal to the base plate 101. The inner edge region 110A is fastened to the light-transmitting layer 108. The light-transmitting layer 108 is fastened to the frame 102 through the cover plate 110. For example, the inner edge region 110A of the cover plate 110 is recessed toward the base plate 101 relative to the outer edge region 110B.

For example, as shown in FIG. 22, the laser 10 further includes a support frame P. An edge of the support frame P is fastened to an outer edge of the cover plate 110 distal to the surface of the package 120. The light-transmitting layer 108 is fastened to the support frame P first, and then the support frame P is fastened to the cover plate 110. For example, the support frame P is a rectangular frame having a beam such that a middle region of the light-transmitting layer 108 can be supported by the support frame P. This can improve the disposition firmness of the light-transmitting layer 108. At least one of the surface of the light-transmitting layer 108 proximal to the base plate 101 and the surface distal to the base plate 101 is further coated with a luminance enhancement film to improve the luminance of light emitted by the laser 10.

For example, as shown in FIG. 6, the package 120, the cover plate 110, and the light-transmitting layer 108 form the closed accommodation space S such that the light-emitting subassemblies 130 are located in the closed accommodation space S to prevent water and oxygen from eroding the light-emitting subassemblies 130. Therefore, the service life of the light-emitting subassemblies 130 can be prolonged.

In some embodiments, referring to FIG. 5 and FIG. 6, the laser 10 further includes a collimating lens group 109. The collimating lens group 109 is disposed on the side of the frame 102 distal to the base plate 101, such as a side of the light-transmitting layer 108 distal to the base plate 101.

For example, the collimating lens group 109 includes a plurality of collimating lenses T corresponding to the plurality of light-emitting chips 104. The collimating lens T is configured to collimate incident laser light and reduce the divergence angle of the incident laser light. The collimating lens T is made of glass. The plurality of collimating lenses T are an integral structure. It should be noted that collimating light means adjusting the divergence angle of the light such that the light is adjusted as close to parallel light as possible. The laser light emitted by the light-emitting chip 104 is reflected by the corresponding reflecting prism 107 to the light-transmitting layer 108. The light-transmitting layer 108 transmits the laser light to the collimating lens T. The laser light is collimated by the collimating lens T and then emergent. This implements light emission of the laser 10.

When the height of the frame 102 becomes small, the height of the laser 10 also becomes small, the total optical path becomes short, and the divergence angle of the laser light emitted by the light-emitting chip 104 becomes small when the laser light reaches the collimating lens T. In this way, at least one dimension of the collimating lens T can be reduced, and the shape of the collimating lens T can no longer be too prolate. Because the area of the collimating lens T is small, the arrangement density of the collimating lenses T is increased and the volume of the collimating lens group 109 can be reduced. Correspondingly, the distance between the light-emitting chip 104 and the corresponding reflecting prism 107 is reduced. This further reduces the volume of the laser.

FIG. 8 to FIG. 11 show another laser according to some embodiments of the present disclosure. Only differences between the laser shown in FIG. 8 to FIG. 11 and the laser shown in FIG. 2 to FIG. 6 are described below, and similarities are not described again. It should be noted that in FIG. 8 to FIG. 11, the same reference numerals as those shown in FIG. 2 to FIG. 6 are used for the same components as those in the laser shown in FIG. 2 to FIG. 6. As shown in FIG. 8, the laser 10 further includes a printed circuit board (PCB) 112. The PCB 112 is disposed on a side of a connector 111 distal to the light-emitting subassembly 130.

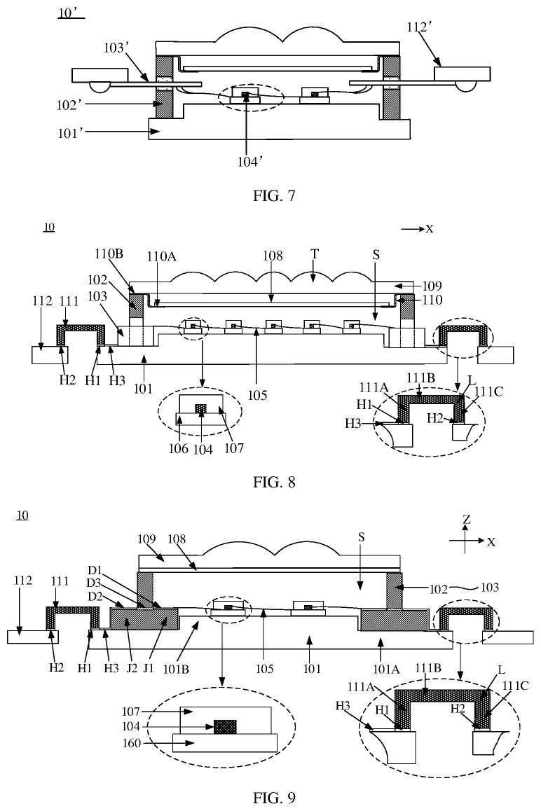

The light-emitting chip 104 usually corresponds to a rated maximum operating temperature (such as 65° C.). If the light-emitting chip is in an environment at a temperature higher than the maximum operating temperature, the service life of the light-emitting chip is affected and the light-emitting chip may be damaged. In the related art, as shown in FIG. 7, the laser 10′ further includes two PCBs 112′. A plurality of conductive pins 103′ are fastened in two opposite sidewalls of the frame 102′ and soldered to the PCBs 112′ on corresponding sides through soldering tin. Due to a high temperature (such as 300° C.) when the conductive pins 103′ and the PCBs 112′ are soldered, heat is conducted to an accommodation space enclosed by the bottom plate 101′ and the frame 102′ through the conductive pins 103′. Consequently, the light-emitting chip 104′ disposed in the accommodation space is prone to impact and damage. Therefore, the laser has low reliability.

To reduce the temperature transmitted to the light-emitting chip when the PCB is fastened and the risk that the light-emitting chip is damaged due to the impact of the temperature, and further improve the reliability of the laser, as shown in FIG. 8, the laser 10 further includes the connector 111. The connector 111 is disposed on a side of the frame 102 distal to the light-emitting chip 104. In this way, heat generated when the connector 111 is fastened can be conducted to the outside of the frame 102 through the connector 111, and is not conducted to the accommodation space S in which the light-emitting chip 104 is located. Therefore, the amount of heat conducted to the light-emitting chip 104 is small, and the risk that the light-emitting chip 104 is damaged can be reduced, to improve the reliability of the laser 10.

In some embodiments, as shown in FIG. 8, the bottom surface of the frame 102 is completely in contact with the base plate 101. For example, the laser 10 further includes a plurality of first pads H1, a plurality of second pads H2, and a connection line H3. The connection line H3 and the plurality of first pads H1 are disposed on the base plate 101. The plurality of first pads H1 are located in an edge region of the base plate 101. The plurality of first pads H1 are connected to the second conductive layer D2 in the corresponding first conductive structure 103 through the corresponding connection line H3. The plurality of second pads H2 are disposed on the PCB 112 and correspond to the plurality of first pads H1. Both ends of the connector 111 are respectively soldered to the first pad H1 and the corresponding second pad H2 such that the second conductive layer D2 can be connected to the PCB 112. For example, both ends of the connector 111 are respectively soldered to the first pad H1 and the corresponding second pad H2 through soldering tin.

For example, in the X direction, the plurality of first pads H1 on the base plate 101 are located in edge regions on two opposite sides of the base plate 101. The first pad H1 on one of the two opposite sides is connected to an anode of a power supply through the PCB 112, and the first pad H1 on the other side is connected to a cathode of the power supply through the PCB 112. Materials of the first pad H1 and the second pad H2 include copper.

In some embodiments, the connector 111 includes at least one bent portion L. As shown in FIG. 8, the connector 111 has two bent portions L. Alternatively, the connector 111 has three or even four bent portions L. This can increase the heat dissipation area of the connector 111. Heat generated when the connector 111 is soldered to the first pad H1 and the second pad H2 can be quickly dissipated through the connector 111. This reduces heat conducted to a region in which the light-emitting chip 104 is located. When the connector 111 is heated, the bent portion L is compressed to some extent. This can release thermal stress and reduce the risk of damage to the connector 111 due to the thermal stress, to ensure the reliability of the connector 111.

For example, the connector 111 includes a first strip portion 111A, a second strip portion 111B, and a third strip portion 111C connected in sequence. The first strip portion 111A is connected to the first pad H1 on the base plate 101. The third strip portion 111C is connected to the second pad H2 on the PCB 112. An extension direction (such as a Z direction) of the first strip portion 111A is perpendicular to the base plate 101. An extension direction (such as the Z direction) of the third strip portion 111C is perpendicular to the PCB 112. This facilitates observation of and adjustment to a welding effect of the first strip portion 111A and the third strip portion 111C with the first pad H1 and the second pad H2 respectively after welding is completed.

In some embodiments, the connector 111 is made of a silver alloy. This material has good heat dissipation performance. This can further improve heat dissipation efficiency during soldering and reduce the heat conducted to the light-emitting chip 104.

FIG. 9 shows an example in which the laser 10 includes one frame 102 and two light-emitting chips 104. Alternatively, the laser 10 includes a plurality of frames 102. Each frame 102 corresponds to a plurality of first conductive structures 103. A second conductive layer D2 in each first conductive structure 103 is connected to the corresponding first pad H1 through the connection line H3 in the base plate 101. The quantity of light-emitting chips 104 can also be adjusted based on a specific situation.

In some embodiments, both the plurality of first conductive structures and the frame are made of ceramic. As shown in FIG. 9, the frame 102 and the first conductive structures 103 are an integral structure. The material of the frame 102 includes ceramic, such as aluminum nitride. Because ceramic is an insulation material, the frame 102 can insulate the base plate 101, the first conductive layer D1, and the second conductive layer D2. In addition, in the case that the frame 102 and the first conductive structures 103 are an integral structure, the bottom surface of the frame 102 has a large area. When the bottom surface is used for welding with the base plate 101, the contact area of the frame 102 with the base plate 101 is large. This can improve welding firmness between the base plate 101 and the frame 102, to improve the reliability of the laser 10.

In some embodiments, in the case that the first conductive structures 103 and the frame 102 are an integral structure, the first conductive layer D1 on the frame 102 and the second conductive layer D2 connected thereto serve as electrode pins. Because the frame 102 does not need to be provided with a hole, the airtightness of the accommodation space S can be improved. In addition, in the process of manufacturing the laser 10, there is no need to insert a first conductive structure into the hole and seal a crack between the first conductive structure and the hole such that the process of manufacturing the laser 10 can be simplified.

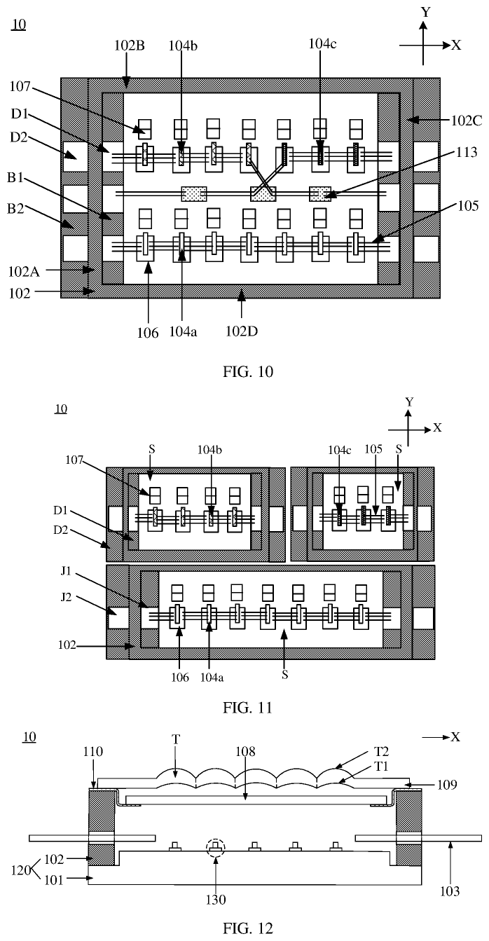

As shown in FIG. 10, in some embodiments, the frame 102 includes four sidewalls connected sequentially end to end: a first sidewall 102A and a third sidewall 102C that are opposite, and a second sidewall 102B and a fourth sidewall 102D that are opposite. The plurality of first conductive structures 103 are located on the first sidewall 102A and the third sidewall 102C.

For example, a plurality of first portions B1 are integrally formed as a first step J1. A plurality of second portions B2 are integrally formed as a second step J2. A plurality of third portions B3 are integrally formed. A plurality of first conductive layers D1 are disposed on the first step J1. A plurality of second conductive layers D2 are disposed on the second step J2. The plurality of first conductive layers D1 correspond to the plurality of second conductive layers D2. The first conductive layer D1 is connected to the corresponding second conductive layer D2 and insulated from the other first conductive layers D1 and the other second conductive layers D2.

Because the frame 102 is insulated, the first conductive layers D1 can be spaced apart and the second conductive layers D2 can be spaced apart such that insulation of the first conductive layers D1 and insulation of the second conductive layers D2 can be achieved. Alternatively, an insulation material is disposed between the adjacent first conductive layers D1 and between the adjacent second conductive layers D2 to further ensure insulation of the first conductive layers D1 and insulation of the second conductive layers D2.

For example, the laser 10 is a monochromatic laser. In this case, only two sets of first conductive layers D1 and second conductive layers D2 connected to each other are disposed on the frame 102. One set of the first conductive layer D1 and the second conductive layer D2 serves as an anode pin, and the other set of the first conductive layer D1 and the second conductive layer D2 serves as a cathode pin.

For another example, the laser 10 is a multicolor laser, and includes at least two types of light-emitting chips 104. The light-emitting chips 104 of each type are connected in series and have two ends respectively connected to two first conductive layers D1. Different types of light-emitting chips 104 are connected to different first conductive layers D1. The two ends of each type of light-emitting chip 104 are two connection ends of the plurality of light-emitting chips 104 connected in series.

In some embodiments, as shown in FIG. 10, at least two types of light-emitting chips 104 are arranged in two rows and a plurality of columns. One row of light-emitting chips 104 includes first-type light-emitting chips 104a. The other row of light-emitting chips 104 includes second-type light-emitting chips 104b and third-type light-emitting chips 104c. The second-type light-emitting chips 104b and the third-type light-emitting chips 104c are respectively located in two regions of the base plate 101. The two regions are sequentially arranged in the row direction (such as the X direction) of the light-emitting chips 104. For example, wavelengths of laser light emitted by the first-type light-emitting chips 104a, the second-type light-emitting chips 104b, and the third-type light-emitting chips 104c decrease sequentially. The first-type light-emitting chips 104a are configured to emit red laser light. The second-type light-emitting chips 104b are configured to emit green laser light. The third-type light-emitting chips 104c are configured to emit blue laser light.

The second-type light-emitting chips 104b and the third-type light-emitting chips 104c are located in the same row. One of an anode pin and a cathode pin of the second-type light-emitting chips 104b is connected to one first conductive layer D1 in the row. One of an anode pin and a cathode pin of the third-type light-emitting chips 104c is connected to the other first conductive layer D1 in the row. The other one of the anode pin and the cathode pin of the second-type light-emitting chips 104b needs to be connected to one first conductive layer D1 in the other row. The other one of the anode pin and the cathode pin of the third-type light-emitting chips 104c needs to be connected to the other first conductive layer D1 in the other row.

In view of this, in some embodiments, as shown in FIG. 10, the laser 10 further includes a plurality of adapters 113 disposed between the two rows of light-emitting chips 104. The plurality of adapters 113 are arranged in one row. An example in which 3 adapters 113 are disposed is used herein. The adapter 113 in the middle is connected to two adapters 113 on both sides thereof. The two adapters 113 on both sides are respectively connected to two first conductive layers D1.

For example, a surface of the adapter 113 distal to the base plate 101 is conductive to adapt the second conductive structure 105. The adapter 113 includes an adapter body and a conductive layer located on a side of the adapter body distal to the base plate 101. The adapter body is made of an insulation material. The conductive layer is made of a conductive material. Dimensions of the surface of the adapter 113 distal to the base plate 101 can be designed based on a disposition requirement of the second conductive structure 105.

The second-type light-emitting chips 104b and the third-type light-emitting chips 104c each have one end connected to one first conductive layer D1 corresponding to a position of the chip and the other end connected to the adapter 113 to connect to the other first conductive layer D1 not corresponding to the position through the adapter 113. For example, the adapter 113 in the middle is located between the second-type light-emitting chips 104b and the third-type light-emitting chips 104c such that the second-type light-emitting chips 104b and the third-type light-emitting chips 104c are connected to the adapter 113. This can meet a condition that the second-type light-emitting chips 104b and the third-type light-emitting chips 104c located in the same row do not share the same set of the first conductive layer D1 and the second conductive layer D2 such that the second-type light-emitting chips 104b and the third-type light-emitting chips 104c are connected to an external power supply and arrangement of the second conductive structure 105 is more orderly.

The adapter 113 in the middle includes two insulated conductive regions. The two conductive regions are disposed on the upper surface of the adapter 113 in the middle. The two conductive regions are configured to respectively connect to the second-type light-emitting chips 104b and the third-type light-emitting chips 104c, to ensure normal current transmission to the second-type light-emitting chip 104b and the third-type light-emitting chip 104c.

For example, one set of the first conductive layer D1 and the second conductive layer D2 on the first sidewall 102A serves as an anode pin, and the other set of the first conductive layer D1 and the second conductive layer D2 on the third sidewall 102C serves as a cathode pin. Further, two first conductive layers D1 connected to each type of light-emitting chip 104 are respectively located on two opposite sides of the frame 102. For example, the second-type light-emitting chips 104b has a left end connected to the first conductive layer D1 on the first sidewall 102A and a right end connected to the first conductive layer D1 on the third sidewall 102C through two adapters 113. The third-type light-emitting chips 104c has a right end connected to the first conductive layer D1 on the third sidewall 102C and a left end connected to the first conductive layer D1 on the first sidewall 102A through two adapters 113.

In some embodiments, the laser 10 includes a plurality of frames 102. Each frame 102 surrounds one type of light-emitting chip 104. FIG. 11 shows an example in which the laser 10 includes three frames 102. The three frames 102 respectively surround the first-type light-emitting chips 104a, the second-type light-emitting chips 104b, and the third-type light-emitting chips 104c. In this way, because the light-emitting chips 104 in the laser 10 are packaged through the plurality of frames 102, a small quantity of light-emitting chips 104 are disposed in an accommodation space S enclosed by each frame 102 and each frame 102 has a small volume and a small contact area with the base plate 101. Because thermal stress during welding of two objects is positively correlated with the contact area of the two objects, when the frames 102 are welded to the base plate 101 in a time-division manner, thermal stress generated in each welding is small. This can reduce the risk that the frames 102 and the base plate 101 are damaged due to the thermal stress during welding.

In some embodiments, referring to FIG. 9, the base plate 101 includes a first region 101A and a second region 101B. The first region 101A surrounds the second region 101B. The second region 101B is convex relative to the first region 101A. The frame 102 is fastened to the first region 101A. The plurality of light-emitting chips 104 are disposed in the second region 101B. The second region 101B is referred to as a patch region of the base plate 101. For example, a height difference between the first region 101A and the second region 101B is approximately the height of the first portion B1 or the second portion B2 of the first conductive structure 103, or may be slightly less than the height. This can further shorten the linear distance between the light-emitting chip 104 and the first conductive layer D1 and the length of the second conductive structure 105 connecting the light-emitting chip 104 and the first conductive layer D1, to ensure high strength of the second conductive structure 105.

FIG. 12 to FIG. 24 show still another laser according to some embodiments of the present disclosure. Only differences between the laser shown in FIG. 12 to FIG. 24 and the laser shown in FIG. 2 to FIG. 6 are described below, and similarities are not described again. It should be noted that in FIG. 12 to FIG. 24, the same reference numerals as those shown in FIG. 2 to FIG. 6 are used for the same components as those in the laser shown in FIG. 2 to FIG. 6. It should be noted that the laser shown in FIG. 12 to FIG. 24 may use the first conductive structures shown in FIG. 1 instead of the first conductive structures shown in FIG. 2 to FIG. 6.

As shown in FIG. 12, the collimating lens T includes a first surface T1 and a second surface T2. The first surface T1 and the second surface T2 are two opposite surfaces of the collimating lens. The first surface T1 is closer to the package 120 than the second surface T2. Laser light emitted by the light-emitting subassembly 130 passes through the light-transmitting layer 108 and is transmitted to the corresponding collimating lens T, and is incident to the collimating lens T through the first surface T1 of the collimating lens T, transmitted in the collimating lens T, and emergent from the collimating lens T through the second surface T2 of the collimating lens T. The first surface T1 is a light incidence surface of the collimating lens T. The second surface T2 is a light emergence surface of the collimating lens T.

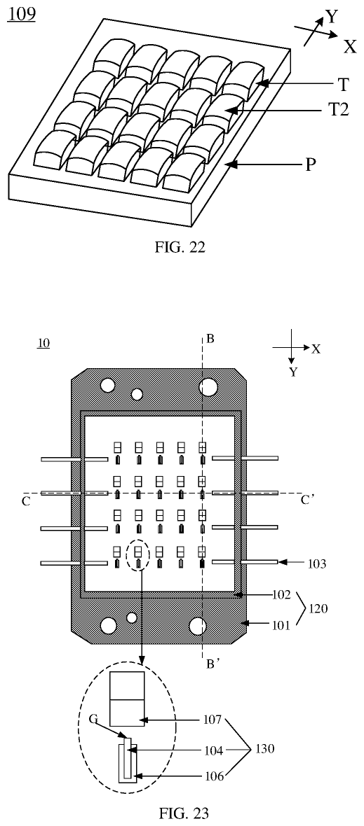

Because the effect of collimating laser light emitted by a laser affects the energy of the laser light, in a laser projection apparatus, the effect of collimating the laser light affects the luminance thereof. The better the effect of collimating the laser light, the higher the luminance thereof, and the better a display effect of a displayed image formed by the laser light. However, the divergence angle of the laser light emitted by the light-emitting subassembly on a fast axis is significantly greater than that on a slow axis. The difference between the divergence angle of the laser light on the fast axis and that on the slow axis is large. The fast axis and the slow axis are directions of two light vectors when light travels. The fast axis is perpendicular to the slow axis. For example, as shown in FIG. 12 (FIG. 12 is a sectional view taken along a line C-C′ in FIG. 23), a slow axis of the laser light transmitted to the collimating lens T is parallel to the X direction. A fast axis of the laser light is perpendicular to the direction of paper.

In the related art, a collimating lens in a collimating lens group includes two opposite surfaces. To improve production efficiency or installation convenience of the collimating lens group, one of the two surfaces of the collimating lens is set as a flat surface, and the other is set as a convex arc surface. The collimating lens collimates the incident laser light through the convex arc surface. The convex arc surface is a part of a spherical surface. Curvatures of the convex arc surface in all directions are equal such that the convex arc surface reduces the divergence angles of the incident laser light on the fast axis and the slow axis to the same extent, and the difference between the divergence angles of the laser light passing through the collimating lens on the fast axis and the slow axis is still large. Consequently, the laser light emitted by the laser has poor collimation.

Adjustment characteristics of the collimating lens T for the divergence angle and the transmission direction of the incident laser light are determined by curvatures of the first surface T1 and the second surface T2. When the curvatures of the first surface T1 and the second surface T2 are different, the shape of the collimating lens T may also be different. In some embodiments of the present disclosure, a decrease in the divergence angle of the laser light incident to the collimating lens on the slow axis can be less than a decrease in the divergence angle on the fast axis through various implementations such that the difference between the divergence angles of the laser light emergent from the collimating lens on the fast axis and the slow axis is reduced, to improve the collimation of the laser light.

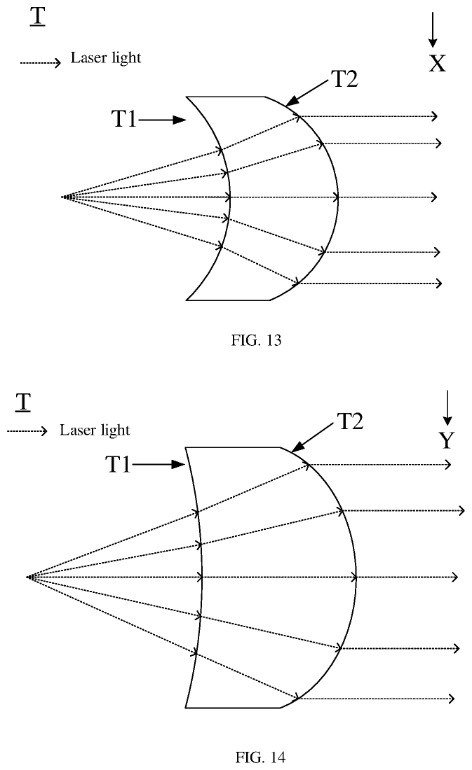

In some embodiments, the first surface T1 of the collimating lens T is configured to increase the divergence angle of the incident laser light on the slow axis. The second surface T2 is configured to decrease the divergence angles of the incident laser light on both the fast axis and the slow axis. As shown in FIG. 13 and FIG. 14, the collimating lens T is cylindrical. The first surface T1 of the collimating lens T is a concave arc surface to increase the divergence angle of the laser light on the slow axis. The second surface T2 includes a convex arc surface to decrease the divergence angles of the incident laser light on both the fast axis and the slow axis. There are various ways to adjust the divergence angles of the laser light through the first surface T1 and the second surface T2.

For example, an entire region of the first surface T1 is a concave arc surface, and an entire region of the second surface T2 is a convex arc surface. The first surface T1 has a radian in a first direction (such as a slow axis direction of the incident laser light, namely the X direction) and a second direction (such as a fast axis direction of the incident laser light, namely the Y direction). A radius of curvature on the slow axis is less than a radius of curvature on the fast axis. The first direction is perpendicular to the second direction. Because a curvature of an arc surface is a reciprocal of a radius of curvature, a curvature of the first surface T1 on the slow axis of the incident laser light is greater than a curvature on the fast axis. That is, a radian of the first surface T1 on the slow axis is greater than a radian on the fast axis.

A concave arc surface has a divergence effect on incident light. The larger a radius of curvature of the concave arc surface, the smaller a bending degree of the concave arc surface, the weaker the divergence effect of the concave arc surface on the light, and the smaller an increase in a divergence angle of the light. Because the radius of curvature of the first surface T1 on the slow axis of the incident laser light is less than the radius of curvature on the fast axis, an increase in the divergence angle of the laser light emitted by the light-emitting subassembly 130 on the fast axis after the laser light passes through the first surface T1 is less than an increase in the divergence angle on the slow axis. Because the divergence angle of the laser light emitted by the light-emitting subassembly 130 on the fast axis is originally greater than the divergence angle on the slow axis, the difference between the divergence angles of the laser light on the slow axis and the fast axis after the laser light passes through the first surface T1 is small. In comparison with a divergence angle of laser light after the laser light is incident to a collimating lens in the related art, the difference between the angles on the fast axis and the slow axis after the laser light passes through the first surface T1 can be reduced in some embodiments of the present disclosure.

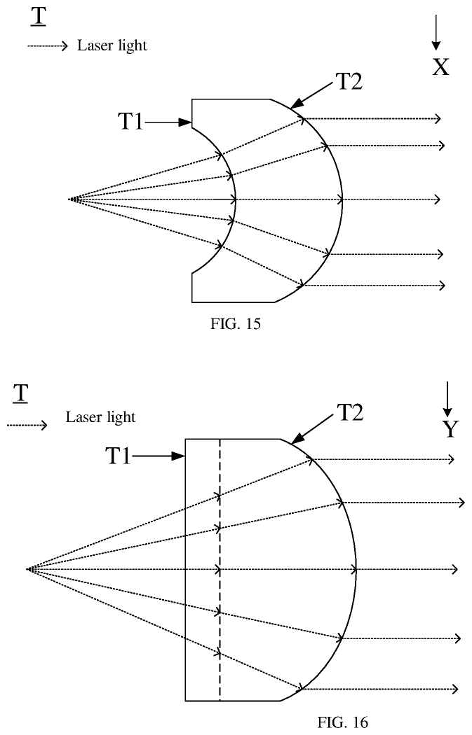

For example, as shown in FIG. 15, a partial region of the first surface T1 is a concave arc surface, and a partial region of the second surface T2 is a convex arc surface. The laser light is incident only to the partial region in which the concave arc surface is located in the first surface T1 and emergent from the partial region in which the convex arc surface is located in the second surface T2.

For another example, referring to FIG. 13 and FIG. 16 or referring to FIG. 15 and FIG. 16, the first surface T1 is a concave cylindrical surface. A straight generatrix of the concave cylindrical surface is parallel to the second direction (for example, parallel to the fast axis direction of the laser light incident to the first surface T1, namely the Y direction in FIG. 16). A cylindrical surface is a curved surface formed by moving a straight line parallel to a given curve. The straight line is referred to as a straight generatrix of the cylindrical surface. For example, the cylindrical surface is a part of a side surface of a cylinder and has a straight generatrix parallel to the height direction of the cylinder. A curvature of the concave cylindrical surface on the fast axis of the incident laser light is 0, a radius of curvature is infinite, and the curvature of the concave cylindrical surface on the slow axis of the incident laser light is greater than 0.

Because the first surface T1 approximates a flat surface on the fast axis of the laser light incident to the first surface T1, a change in the divergence angle of the laser light incident to the first surface T1 on the fast axis is close to a change in the divergence angle of the laser light incident to flat glass, and the divergence angle of the laser light on the fast axis is basically unchanged. On the slow axis of the laser light incident to the first surface T1, a bending degree of the first surface T1 is large and the increase in the divergence angle of the laser light on the slow axis is large. As shown in FIG. 13 or FIG. 15, the divergence angle of the laser light on the slow axis increases after the laser light is incident to the first surface T1. As shown in FIG. 16, the divergence angle of the laser light on the fast axis is basically unchanged after the laser light is incident to the first surface T1. In this way, when the laser light is transmitted in the collimating lens T to the convex arc surface of the second surface T2, the difference between the divergence angles on the slow axis and the fast axis is small.

The laser light incident to the collimating lens is further collimated by the convex arc surface of the second surface T2 and then emergent after the divergence angles on the fast axis and the slow axis of the laser light are adjusted through the concave arc surface of the first surface T1 or after the divergence angle on the slow axis of the laser light is adjusted, to ensure that the laser light emergent from the collimating lens T has a good collimation effect.

For example, curvatures of the convex arc surface of the second surface T2 on the slow axis and the fast axis of the incident laser light are the same. That is, curvatures of the convex arc surface of the second surface T2 in the first direction and the second direction are the same. For example, the convex arc surface is a part of a spherical surface. Because the concave arc surface of the first surface T1 already makes the difference between the divergence angles of the laser light on the fast axis and the slow axis small, the second surface T2 can merely collimate the laser light as a whole to make the decrease in the divergence angle of the laser light on the fast axis similar to the decrease in the divergence angle on the slow axis. In this way, there is no need to design different curvatures of the convex arc surface of the second surface T2 in different directions, and the process of manufacturing the collimating lens is simplified.

For another example, the convex arc surface of the second surface T2 is a free-form surface. A radius of curvature of the convex arc surface on the slow axis of the incident laser light is greater than a radius of curvature on the fast axis. That is, the radius of curvature of the convex arc surface of the second surface T2 in the first direction is greater than the radius of curvature in the second direction. A curvature of the convex arc surface on the slow axis of the incident laser light is less than a curvature on the fast axis. A surface with different radii of curvature in different directions is referred to as a free-form surface. The second surface T2 may resemble a part of a spherical surface of a rugby ball. A convex arc surface has a convergence effect on incident light. The smaller a radius of curvature of the convex arc surface, the larger a bending degree of the convex arc surface, the stronger the convergence effect of the convex arc surface on the light, and the larger a decrease in the divergence angle of the light. In this way, the convex arc surface can adjust the divergence angles of the incident laser light on the fast axis and the slow axis again such that the decrease in the divergence angle of the laser light on the slow axis is less than the decrease in the divergence angle on the fast axis, to further reduce the difference between the divergence angles of the laser light emergent from the collimating lens on the fast axis and the slow axis. In this way, the convex arc surface collimates the incident laser light, and a good collimation effect of the laser light emergent from the collimating lens T can be ensured. As shown in FIG. 13 to FIG. 16, after the laser light is emergent from the convex arc surface of the second surface T2, the laser light approaches parallel light on both the fast axis and the slow axis.

In some embodiments, a focal length of the collimating lens T is set first, and then specific parameters of the collimating lens T are determined based on the focal length, such as radii of curvature of the convex arc surface of the collimating lens T on the slow axis and the fast axis of the incident laser light and a radius of curvature of the concave arc surface. In some embodiments, a plurality of implementations of the first surface T1 of the collimating lens T can be arbitrarily combined with a plurality of implementations of the second surface T2 such that four types of collimating lenses with different shapes can be obtained. In the first-type collimating lens, the first surface T1 and the second surface T2 are both free-form surfaces. In the second-type collimating lens, the first surface T1 is a concave cylindrical surface and the second surface T2 is a convex free-form surface. In the third-type collimating lens, the first surface T1 is a free-form surface and the second surface T2 is a spherical surface. In the fourth-type collimating lens, the first surface T1 is a concave cylindrical surface and the second surface T2 is a spherical surface. In the four types of collimating lenses, radii of curvature of the concave arc surface in the first surface T1 and the convex arc surface in the second surface T2 satisfy a specific relationship to ensure that the collimating lens T has a good collimation effect on the incident laser light.

In some embodiments, the radius of curvature of the concave arc surface of the collimating lens T is greater than that of the convex arc surface. For example, for the collimating lens T in which the entire region of the first surface T1 is a concave arc surface or the partial region of the first surface T1 is a concave arc surface, radii of curvature of the concave arc surface on the fast axis and the slow axis of the incident laser light are greater than radii of curvature of the convex arc surface on the fast axis and the slow axis. For the collimating lens T in which the first surface T1 is a concave cylindrical surface, the concave cylindrical surface is curved only on the slow axis of the incident laser light. The radius of curvature of the concave arc surface is a radius of curvature of the concave arc surface on the slow axis. In some embodiments, the radius of curvature of the concave arc surface of the collimating lens on the fast axis of the incident laser light is greater than the radius of curvature of the convex arc surface on the fast axis, and the radius of curvature of the concave arc surface on the slow axis of the incident laser light is greater than the radius of curvature of the convex arc surface on the slow axis. This can ensure that the collimating lens collimates and converges light to make the divergence angle of the laser light emergent from the collimating lens less than the divergence angle of the laser light incident to the collimating lens. However, it is difficult to make the divergence angles of the laser light on the slow axis and the fast axis the same because the concave arc surface can reduce the difference between the divergence angles of the incident laser light on the slow axis and the fast axis only to some extent. Therefore, further adjustment is needed through the convex arc surface to ensure consistency of collimation effects of the laser light finally emergent from the collimating lens in different directions.

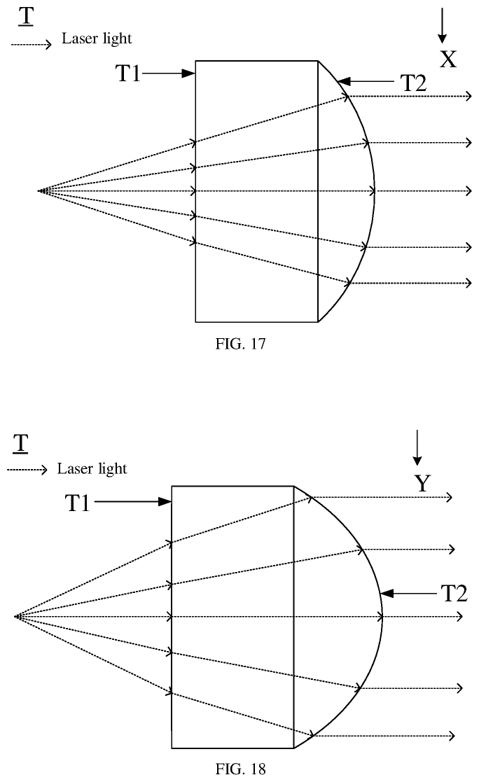

In some embodiments, as shown in FIG. 17 and FIG. 18, the first surface T1 of the collimating lens is a flat surface and the second surface T2 of the collimating lens is a convex arc surface. The convex arc surface is a free-form surface. The radius of curvature of the convex arc surface on the slow axis (in the X direction) of the incident laser light is greater than the radius of curvature on the fast axis (in the Y direction).

Because the first surface T1 of the collimating lens is a flat surface, the first surface T1 changes the divergence angle of the incident laser light on the slow axis to the same extent as the divergence angle on the fast axis. After the laser light is incident to the first surface T1, the difference between the divergence angles of the laser light on the fast axis and the slow axis is still large. Consequently, the difference between the divergence angles of the laser light transmitted to the convex arc surface of the collimating lens T on the fast axis and the slow axis is still large. Because the radius of curvature of the convex arc surface on the slow axis of the incident laser light is greater than the radius of curvature on the fast axis, the convergence effect of the convex arc surface on the fast axis of the incident laser light is stronger than that on the slow axis, and the difference between the divergence angles of the laser light emergent from the collimating lens T (namely the laser light emergent from the convex arc surface) on the fast axis and the slow axis is reduced.

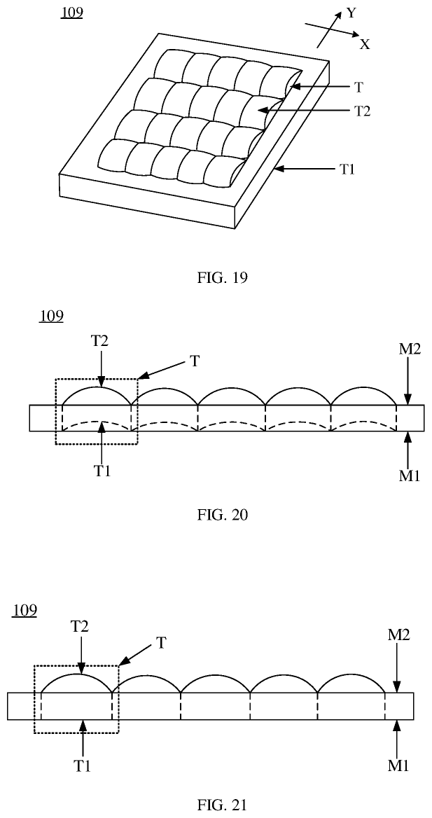

In some embodiments, as shown in FIG. 19, the width of the collimating lens T on the fast axis (in the Y direction) of the incident laser light is greater than the width on the slow axis (in the X direction). That is, a top view of the collimating lens T is rectangular. When the laser light emitted by the light-emitting subassembly 130 is incident to the collimating lens T, a light spot is elliptical. A major axis of the elliptical light spot is parallel to a long side direction of the rectangular collimating lens T. A short axis of the elliptical light spot is parallel to a short side direction of the rectangular collimating lens T. This can ensure a high degree of matching between a shape of the light spot incident to the collimating lens T and a shape of the collimating lens T. Dimension waste of the collimating lens T is avoided on the basis of ensuring that all laser light is incident to the collimating lens T. This is conducive to miniaturization of the laser 10.

Various implementations of the collimating lens group 109 are described below with reference to the accompanying drawings.

In some embodiments, the collimating lens group 109 is an integral structure. As shown in FIG. 20 and FIG. 21, the collimating lens group 109 includes a light incidence surface M1 and a light emergence surface M2. The light incidence surface M1 and the light emergence surface M2 are two opposite surfaces of the collimating lens group 109. The light incidence surface M1 is closer to the package 120 than the light emergence surface M2. The light incidence surface M1 includes the first surface T1 of each collimating lens T in the collimating lens group 109. The light emergence surface M2 includes the second surface T2 of each collimating lens T. For example, as shown in FIG. 20, the light incidence surface M1 includes a plurality of concave arc surfaces. The light emergence surface M2 includes a plurality of convex arc surfaces. A portion at which each concave arc surface and the corresponding convex arc surface are located is one collimating lens T. An orthographic projection of each convex arc surface on the light incidence surface of the collimating lens group 109 is in coincidence with an orthographic projection of the corresponding convex arc surface on the light incidence surface. For another example, as shown in FIG. 21, the light incidence surface M1 is a flat surface. The light emergence surface M2 includes a plurality of convex arc surfaces. A portion at which each convex arc surface is located is one collimating lens T.

In some other embodiments, as shown in FIG. 22, the collimating lens group 109 is composed of a plurality of independent collimating lenses T. For example, the support frame P has a plurality of hollowed-out regions (not shown in the figure). Each collimating lens T covers one of the plurality of hollowed-out regions. The plurality of hollowed-out regions correspond to the plurality of light-emitting subassemblies 130 in the laser 10. The laser light emitted by each light-emitting subassembly 130 passes through the corresponding hollowed-out region and is transmitted to the collimating lens T covering the hollowed-out region.

In some embodiments, the laser 10 is a multi-chip laser diode (MCL) laser. As shown in FIG. 23, the plurality of light-emitting subassemblies 130 in the laser 10 are arranged in an array. FIG. 23 shows an example in which the laser 10 includes 20 light-emitting subassemblies 130 and the light-emitting subassemblies 130 are arranged in four rows and five columns.

When the laser 10 is a monochromatic MCL laser, parameters of all collimating lenses T in the collimating lens group 109 are the same. When the laser 10 is a multicolor MCL laser, it includes a plurality of types of light-emitting subassemblies 130. The collimating lens group 109 includes a plurality of collimating lenses T having different parameters. Divergence angles of laser light emitted by different types of light-emitting subassemblies 130 are different. The corresponding collimating lens T in the collimating lens group 109 can be designed based on the divergence angle of the laser light emitted by each light-emitting subassembly 130. For example, for the multicolor MCL laser, the parameters of all collimating lenses T in the collimating lens group 109 are alternatively the same.

In some embodiments, an example in which the laser 10 is a multicolor MCL laser is used. The plurality of light-emitting subassemblies 130 include a first light-emitting subassembly configured to emit laser light of a first color and a second light-emitting subassembly configured to emit laser light of a second color. The divergence angle of the laser light of the first color is less than the divergence angle of the laser light of the second color. The collimating lens group 109 meets a condition that a decrease in the divergence angle of the incident laser light by the collimating lens corresponding to the first light-emitting subassembly is less than a decrease in the divergence angle of the incident laser light by the collimating lens corresponding to the second light-emitting subassembly. The radius of curvature of the concave arc surface of the collimating lens corresponding to the first light-emitting subassembly is less than that of the concave arc surface of the collimating lens corresponding to the second light-emitting subassembly; and/or the radius of curvature of the convex arc surface of the collimating lens corresponding to the first light-emitting subassembly is greater than that of the concave arc surface of the collimating lens corresponding to the second light-emitting subassembly.

For example, the first color includes blue and green. The first light-emitting subassembly includes a blue light-emitting subassembly and a green light-emitting subassembly. The second color is red. The second light-emitting subassembly is a red light-emitting subassembly. A divergence angle of red laser light emitted by the red light-emitting subassembly is greater than that of blue laser light emitted by the blue light-emitting subassembly, and greater than that of green laser light emitted by the green light-emitting subassembly. For example, divergence angles of the red laser light on the fast axis and the slow axis are both greater than those of the green laser light and the blue laser light on the fast axis and the slow axis. Alternatively, the divergence angle of the red laser light on the fast axis is greater than the divergence angles of the green laser light and the blue laser light on the fast axis, and the divergence angle of the red laser light on the slow axis is greater than the divergence angles of the green laser light and the blue laser light on the slow axis, but the divergence angle of the red laser light on the slow axis is less than the divergence angles of the blue laser light and the green laser light on the fast axis. The decrease in the divergence angle of the laser light by the collimating lens corresponding to the light-emitting subassembly emitting the laser light of each color can be adjusted based on the divergence angles of the red laser light, the blue laser light, and the green laser light on the fast axis and the slow axis. For example, the radii of curvature of the convex arc surface of the collimating lens on the fast axis and the slow axis can be adjusted.

For example, the divergence angle of the blue laser light on the fast axis is greater than the divergence angle of the red laser light on the slow axis and less than the divergence angle of the red laser light on the fast axis of the incident laser light. In this case, if the first surface T1 of the collimating lens T is a concave arc surface or a concave cylindrical surface and the second surface T2 is a convex arc surface, the radius of curvature of the concave arc surface of the collimating lens to which the blue laser light is incident on the slow axis is greater than the radius of curvature of the concave arc surface of the collimating lens to which the red laser light is incident on the slow axis, and less than the radius of curvature of the concave arc surface of the collimating lens to which the red laser light is incident on the fast axis. Alternatively, the radius of curvature of the convex arc surface of the collimating lens to which the blue laser light is incident on the slow axis is less than the radius of curvature of the convex arc surface of the collimating lens to which the red laser light is incident on the slow axis, and greater than the radius of curvature of the concave arc surface of the collimating lens to which the red laser light is incident on the fast axis. If the first surface T1 of the collimating lens T in the collimating lens group is a flat surface and the second surface T2 is a convex arc surface, the radius of curvature of the convex arc surface of the collimating lens to which the blue laser light is incident on the fast axis is greater than the radius of curvature of the convex arc surface of the collimating lens to which the red laser light is incident on the fast axis, and less than the radius of curvature of the convex arc surface of the collimating lens to which the red laser light is incident on the slow axis. Other relationships between divergence angles of laser light of all colors can be deduced by analogy. Details are not described herein.

In some embodiments, a plurality of light-emitting points are provided in the red light-emitting subassembly in the laser, and only one light-emitting point is provided in the blue light-emitting subassembly and the green light-emitting subassembly. A spot of laser light emitted by each light-emitting subassembly in the laser 10 is prolate. An aspect ratio of a spot formed after the laser light is emergent from the collimating lens can be reduced.

For example, the plurality of light-emitting chips 104 in the laser 10 are arranged in an array. The plurality of collimating lenses T in the collimating lens group 109 are also arranged in an array. The row direction of the light-emitting chips 104 is the same as that of the collimating lenses T. The column direction of the light-emitting chips 104 is the same as that of the collimating lenses T. A light-emitting direction of the light-emitting chips 104 is perpendicular to the row direction of the plurality of light-emitting chips 104 and parallel to the column direction of the plurality of light-emitting chips 104. The slow axis of the laser light emitted by the light-emitting chip 104 is parallel to the row direction. When the laser light is incident to the collimating lens group 109, the slow axis is parallel to the row direction of the collimating lenses T, and the fast axis is parallel to the column direction of the collimating lenses T.

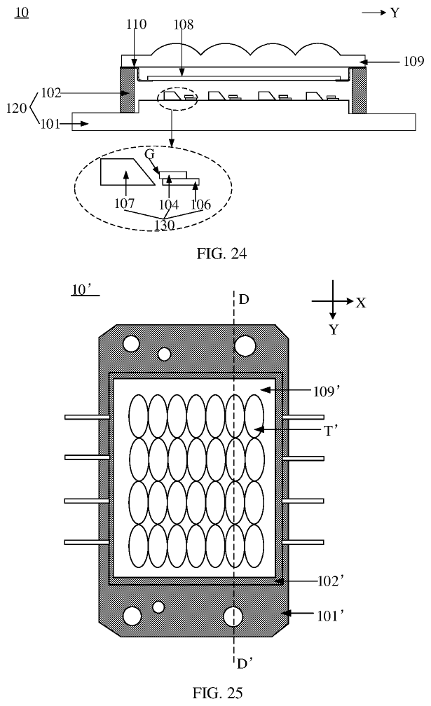

In some embodiments, referring to FIG. 23 and FIG. 24, the light-emitting chip 104 is a cuboid and includes an end surface G opposite to the corresponding reflecting prism 107. Laser light is emitted from the end surface G. An actual light-emitting region in the end surface G is rectangular. The rectangular light-emitting region has a length direction parallel to the surface of the base plate 101 and a width direction perpendicular to the surface of the base plate 101. The fast axis of the laser light emitted by the light-emitting chip 104 is parallel to the width direction, and the slow axis of the laser light is parallel to the length direction. For example, a collimation effect of the collimating lens T on laser light in a direction is related to the width of a light-emitting region of the laser light in the direction. If only the collimating lens with the same curvature on the slow axis and the fast axis is used to collimate the laser light emitted by the light-emitting chip 104, when the divergence angle on the fast axis is reduced to ensure that the laser light is collimated on the fast axis, there is still a difference between the divergence angles on the slow axis and the fast axis. This is not conducive to shaping and subsequent transmission of the laser light. In some embodiments of the present disclosure, a collimating lens whose first surface is set to a concave cylindrical surface, a free-form surface, or a flat surface and second surface is set to a free-form surface can adjust the divergence angles of laser light in the slow axis direction and the fast axis direction. This can improve the shaping and collimation effects of the collimating lens on laser light.

In the related art, as shown in FIG. 25, the light-emitting subassemblies in the laser 10′ are regularly arranged in rows and columns, and necessary gaps exist in the row direction and the column direction of the light-emitting subassemblies. Correspondingly, collimating lenses T′ in a collimating lens group 109′ are regularly arranged in rows and columns. The laser light emitted by the light-emitting subassembly has an opening angle. To completely receive the laser light emitted by the corresponding light-emitting subassembly, an area of an orthographic projection of the collimating lens T′ on the base plate needs to be greater than an area of a light spot formed by the laser light emitted by the corresponding light-emitting subassembly. There is an invalid light processing region between the adjacent collimating lenses T′. Laser light emergent from this region is stray light, which is difficult to be received and utilized by a subsequent optical element, resulting in light loss. The larger the gap between the light-emitting subassemblies in the row direction and the column direction, the more light loss.

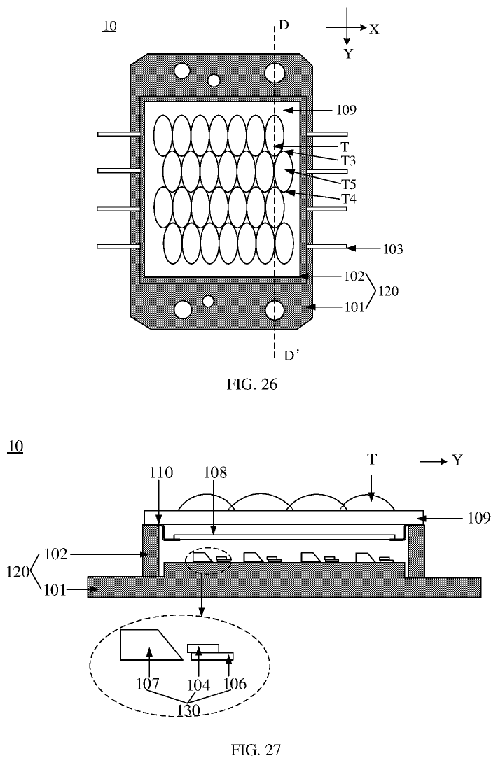

FIG. 26 to FIG. 31 show yet another laser according to some embodiments of the present disclosure. Only differences between the laser shown in FIG. 26 to FIG. 31 and the laser shown in FIG. 2 to FIG. 6 are described below, and similarities are not described again. It should be noted that in FIG. 26 to FIG. 31, the same reference numerals as those shown in FIG. 2 to FIG. 6 are used for the same components as those in the laser shown in FIG. 2 to FIG. 6. It should be noted that the laser shown in FIG. 26 to FIG. 31 may use the first conductive structures shown in FIG. 1 instead of the first conductive structures shown in FIG. 2 to FIG. 6. An arrangement manner of the collimating lenses T in some embodiments of the present disclosure is described below.

In some embodiments, the collimating lens T is long-strip-shaped. The maximum length of the collimating lens T in a first direction is greater than the maximum length in a second direction. The first direction is perpendicular to the second direction. The first direction is a column direction of the collimating lens T. The second direction is a row direction of the collimating lens T. As shown in FIG. 26, the collimating lens T includes two end portions and a middle portion T5 located between the two end portions in the column direction. The two end portions include the upper end portion T3 and the lower end portion T4. The width of the upper end portion T3 and the width of the lower end portion T4 are less than the width of the middle portion T5. It should be noted that the widths of the end portions and the middle portion are widths in the row direction. The end portions and the middle portion of the collimating lens are merely relative concepts. The end portions merely indicate partial regions at both ends of the collimating lens, and the middle portion indicates a region other than the end portions of the collimating lens, which are not regions obtained through accurate division. For example, an orthographic projection of each collimating lens T on the base plate 101 is an ellipse. The ellipse has a major axis parallel to the column direction (Y direction) of the collimating lens T and a minor axis parallel to the row direction (X direction) of the collimating lens T.

An initial spot of the laser light emitted by the light-emitting subassembly 130 has a smaller dimension on the fast axis than a dimension on the slow axis. When the laser light emitted by the light-emitting subassembly 130 propagates in the accommodation space S of the package 120, passes through the light-transmitting layer 108, and is incident to the corresponding collimating lens T, the spot of the laser light is elliptical. A major axis of the elliptical spot is parallel to the column direction of the collimating lens T. A minor axis of the elliptical spot is parallel to the row direction of the collimating lens T. Because a maximum length of the collimating lens T in the column direction is greater than a maximum length in the row direction, the widths of the upper end portion T3 and the lower end portion T4 of the collimating lens T in the column direction are less than the width of the middle portion T5. This can ensure that the shape of the collimating lens T is closer to the shape of the spot formed by the laser light on the collimating lens T and reduce the size of the collimating lens T on the basis of ensuring that the laser light is received.

In some embodiments, as shown in FIG. 26, any two adjacent rows of collimating lenses T in a plurality of rows of collimating lenses T of the collimating lens group 109 are staggered. That the two rows of collimating lenses T are staggered means that the two rows of collimating lenses T are staggered in the column direction (Y direction). The two rows of collimating lenses T are not aligned in the column direction. That is, a line connecting two adjacent collimating lenses T in the two rows is not parallel to the column direction. The line connecting the two collimating lenses T is a line connecting centers of the two collimating lenses T. The two rows of collimating lenses T are completely or partially staggered. Completely staggered means that any two collimating lenses T in the two rows of collimating lenses T are not aligned in the column direction. Partially staggered means that some collimating lenses T in the two rows of collimating lenses T are aligned in the column direction and some collimating lenses T are not aligned in the column direction. An example in which any two adjacent rows of collimating lenses T are completely staggered in the column direction is used in some embodiments of the present disclosure. When the two rows of collimating lenses T are staggered, each collimating lens T in one row of collimating lenses T is located between two adjacent collimating lenses T in the adjacent row of collimating lenses T or located outside the adjacent row of collimating lenses T in the row direction. For example, in FIG. 26, the second collimating lens T in the first row of collimating lenses T is located between the first collimating lens T and the second collimating lens T in the second row of collimating lenses T in the X direction. The first collimating lens T in the first row of collimating lenses T is located on the left side of the second row of collimating lenses T and outside the second row of collimating lenses T in the X direction.

In any two adjacent rows of collimating lenses T in the collimating lens group 109, an end portion of a collimating lens T in one row of collimating lenses T close to the other row of collimating lenses T is at least partially located between two end portions of two adjacent collimating lenses T in the other row of collimating lenses T. In the two adjacent rows of collimating lenses T, between end portions of any two adjacent collimating lenses T in the same row close to the other row of collimating lenses T, an end portion of one collimating lens T in the other row of collimating lenses T is at least partially located. As shown in FIG. 27, on a reference plane parallel to the column direction, orthographic projections of two adjacent rows of collimating lenses are overlapped. For example, for the first row of collimating lenses T and the second row of collimating lenses T in FIG. 26, the lower end portion of the second collimating lens T in the first row of collimating lenses T is located between the upper end portions of the first collimating lens T and the second collimating lens T in the second row of collimating lenses T. An upper end portion of one collimating lens T in the second row of collimating lenses T is located between lower end portions of every two adjacent collimating lenses T in the first row of collimating lenses T. A lower end portion of one collimating lens T in the first row of collimating lenses T is located between upper end portions of every two adjacent collimating lenses T in the second row of collimating lenses T.

In some embodiments of the present disclosure, as shown in FIG. 26, the collimating lenses T in adjacent rows are staggered. A space between end portions of two adjacent collimating lenses T in each row is occupied by an end portion of a collimating lens T in the other row. This can improve space utilization in the collimating lens group 109 and make the arrangement of the collimating lenses T more compact. In comparison with the related art, a gap between the adjacent collimating lenses T is small and an arrangement density is large. The laser light emitted by the light-emitting subassembly 130 can be incident to the collimating lens T as much as possible, instead of an invalid gap between the collimating lenses T. Therefore, the laser light emitted by the light-emitting subassembly can be utilized more and optical loss of the laser 10 is reduced. In addition, because the arrangement of the collimating lenses T is compact, an area of a region occupied by a specific quantity of collimating lenses T is small. Therefore, the light-emitting subassemblies and collimating lenses in the laser 10 are disposed with only a small volume. This is conducive to the miniaturization of the laser 10.

FIG. 26 shows an example in which the orthographic projection of the collimating lens T on the base plate 101 is elliptical. The orthographic projection of the collimating lens T on the base plate 101 may alternatively be of another shape. For ease of description, the shape of the orthographic projection of the collimating lens T on the base plate 101 is simply referred to as the shape of the collimating lens T below.

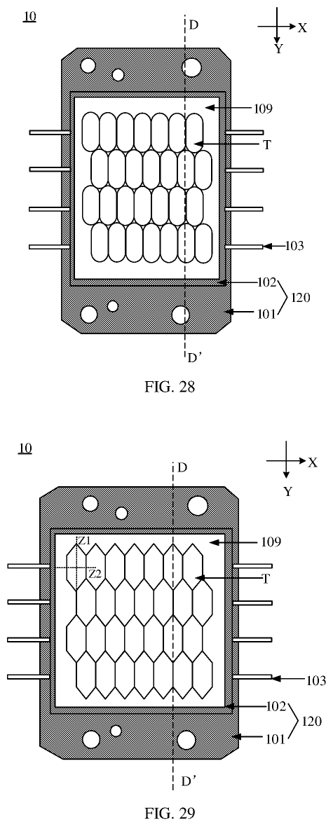

In some embodiments, as shown in FIG. 28, the orthographic projection of the collimating lens T on the base plate 101 is in a capsule shape. The capsule shape is enclosed by two opposite and parallel straight edges and two opposite arc edges. The capsule shape is equivalent to a shape obtained by cutting off a part of each of left and right ends of an ellipse in a major axis direction of the ellipse or a shape obtained by cutting off a part of each of two opposite ends of a circle in a diameter direction of the circle.

In some other embodiments, as shown in FIG. 29, the orthographic projection of the collimating lens T on the base plate 101 is a hexagon. The maximum length of the hexagon in the Y direction is greater than the maximum length in the X direction. Adjacent edges of any adjacent collimating lenses T coincide. The collimating lenses T in the collimating lens group 109 are arranged in a honeycomb shape. The hexagon is an axisymmetric figure with one axis of symmetry parallel to the Y direction. The hexagon may further have another axis of symmetry parallel to the X direction. For example, the first collimating lens T in the first row of collimating lenses T includes a first axis of symmetry Z1 and a second axis of symmetry Z2. The first axis of symmetry Z1 is parallel to the Y direction. The second axis of symmetry Z2 is parallel to the X direction. The first axis of symmetry Z1 is a straight line on which one diagonal of the hexagon is located and bisects two diagonal angles of the hexagon.

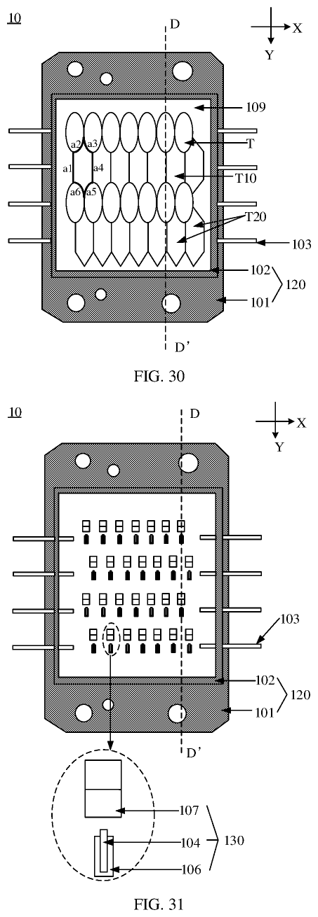

In some embodiments, the collimating lens group 109 includes collimating lenses T having a plurality of shapes. The collimating lenses T include a first-type collimating lens T10 whose orthographic projection on the base plate 101 is in a target shape. As shown in FIG. 30, three adjacent rows of collimating lenses T (such as the first three rows) in the collimating lens group 109 meet the following condition: In the two rows of collimating lenses T (namely the first row and the third row) respectively located at two ends of the three rows of collimating lenses T, an orthographic projection of each collimating lens T on the base plate 101 is elliptical. The collimating lens T in the middle row is the first-type collimating lens T10. The target shape is enclosed by six edges. Referring to the first collimating lens T in the second row in FIG. 30, the six edges are labeled a1, a2, a3, a4, a5, and a6. For example, the six edges include parallel and opposite straight edges a1 and a4, arc edges a2 and a3 each connected to one end of one of the two straight edges, and arc edges a5 and a6 each connected the other end of one of the two straight edges. The arc edges are recessed toward the inside of the target shape. The straight edges a1 and a4 are parallel to the Y direction. One end of each of the two straight edges is an upper end. The other end of each of the two straight edges is a lower end. In some embodiments, referring to FIG. 30, the collimating lens T further includes a second-type collimating lens T20 whose orthographic projection on the base plate 101 is in an auxiliary shape. The auxiliary shape is similar to the target shape except that an edge of the second-type collimating lens T20 that is not adjacent to another collimating lens T is a straight edge. For similarities between the auxiliary shape and the target shape, refer to the foregoing description of the target shape. Details are not described herein again. For example, the second-type collimating lens T20 is located at the edge of the collimating lens group 109. As shown in FIG. 30, the collimating lens T in the fourth row is in the auxiliary shape. The rightmost collimating lens T in the second row is also in the auxiliary shape. Alternatively, the collimating lens T in the fourth row and the rightmost collimating lens T in the second row in FIG. 30 are in the target shape. For example, the edge of the second-type collimating lens T20 that is not adjacent to another collimating lens is a partial edge of an ellipse. In this case, the auxiliary shape is equivalent to changing a part of the ellipse that needs to be adjacent to another collimating lens into a straight edge or an inwardly concave arc edge with the other parts are unchanged.

In some embodiments, any two adjacent collimating lenses T in adjacent rows are in contact with each other. For example, as shown in FIG. 26, FIG. 28, FIG. 29, and FIG. 30, the first collimating lens T and the second collimating lens T in the first row of collimating lenses T are adjacent to the first collimating lens T in the second row of collimating lenses T. Lower end portions of the first collimating lens T and the second collimating lens T in the first row of collimating lenses T are in contact with the upper end portion of the first collimating lens T in the second row of collimating lenses T. As shown in FIG. 26 and FIG. 28, when the collimating lenses T are elliptical or in the capsule shape, only small parts of edges of two adjacent collimating lenses in adjacent rows may be in contact with each other. As shown in FIG. 29, when the collimating lenses T are hexagonal, two adjacent collimating lenses in adjacent rows have at least one edge coinciding. For example, the first collimating lens T in the first row of collimating lenses T and the first collimating lens T in the second row of collimating lenses T have one edge coinciding. In the case of FIG. 30, in adjacent rows of collimating lenses T, an edge of the first-type collimating lens T10 in one row is in coincidence with an edge of the adjacent elliptical collimating lens T in the other row. An edge of the second-type collimating lens T20 in one row is in coincidence with an edge of the adjacent elliptical collimating lens T in the other row.

In some embodiments, any two adjacent collimating lenses in the same row are in contact with each other. For example, as shown in FIG. 26, FIG. 28, FIG. 29, and FIG. 30, edges of the first collimating lens T and the second collimating lens T in the first row of collimating lenses T close to each other are in contact with each other. For example, as shown in FIG. 26, when the collimating lenses T are elliptical, only small parts of edges of two adjacent collimating lenses T in the same row are in contact with each other. For example, the right edge of the first collimating lens T in the first row is in contact with the left edge of the second collimating lens T at only one point. As shown in FIG. 28 and FIG. 29, when the collimating lenses T are in the capsule shape or hexagonal, two adjacent collimating lenses in the same row have at least one edge coinciding. For example, the right edge of the first collimating lens T in the first row of collimating lenses T is in coincidence with the left edge of the second collimating lens T. In the case of FIG. 30, in any row of elliptical collimating lenses T, only small parts of edges of adjacent two collimating lenses T are in contact with each other. In any row of collimating lenses in the target shape or auxiliary shape, edges of adjacent two collimating lenses coincide. When adjacent collimating lenses T are in contact with each other, the space utilization of the collimating lenses can be further improved and area waste of the collimating lens group 109 can be avoided. Alternatively, there is a gap between adjacent collimating lenses T in the collimating lens group 109.

The collimating lens T is configured to collimate the laser light emitted by the corresponding light-emitting subassembly 130. To achieve normal operation of the laser 10, it is necessary to ensure that the laser light emitted by each light-emitting subassembly 130 is incident to the corresponding collimating lens T. Therefore, the arrangement manner of the collimating lenses T in the laser 10 needs to correspond to that of the light-emitting subassemblies 130. In some embodiments, as shown in FIG. 31, the arrangement manner of the plurality of light-emitting subassemblies 130 is the same as that of the collimating lenses T shown in FIG. 26, FIG. 28, FIG. 29, and FIG. 30. That is, the plurality of light-emitting subassemblies 130 are arranged in a plurality of rows, and any two adjacent rows of light-emitting subassemblies 130 are staggered. For the staggered arrangement of the light-emitting subassemblies 130, reference may be made to the related description of the staggered arrangement of the collimating lenses T in the embodiments of the present disclosure. Details are not described herein again.

In the collimating lens group 109 of the laser 10, collimating lenses T in spaced rows may be staggered or aligned in the column direction. An example in which collimating lenses T in spaced rows are aligned in the column direction is used in some embodiments of the present disclosure. Spaced rows of collimating lenses are two rows of collimating lenses spaced apart by one row, namely two rows of collimating lenses located on both sides of and adjacent to any row of collimating lenses T in the column direction in the collimating lens group 109. For example, in the collimating lens group 109 shown in FIG. 26, FIG. 28, FIG. 29, and FIG. 30, the first row of collimating lenses T and the third row of collimating lenses T are spaced rows of collimating lenses T aligned in the column direction. The second row of collimating lenses T and the fourth row of collimating lenses T are also spaced rows of collimating lenses T aligned in the column direction. That two rows of collimating lenses are aligned in the column direction means that one of two collimating lenses respectively located in the two rows is located directly below the other, and a line connecting the two collimating lenses is parallel to the column direction.

In some embodiments, quantities of collimating lenses T in all rows in the collimating lens group 109 are equal. FIG. 26, FIG. 28, FIG. 29, and FIG. 30 show an example in which there are seven collimating lenses T in each row in the collimating lens group 109. Certainly, quantities of collimating lenses T in different rows may alternatively not be equal. The quantity of collimating lenses T can be determined based on a disposition requirement of the light-emitting subassemblies 130. For example, if the required luminance of the laser 10 can be achieved through 20 light-emitting chips 104, the laser 10 needs to include 20 light-emitting subassemblies 130. Correspondingly, the collimating lens group 109 needs to include 20 collimating lenses T. For example, the distance between any two adjacent light-emitting chips 104 in the row direction is equal.

The light-emitting chip 104 generates heat when emitting light, and the heat can be diffused to the surroundings. In a middle region of the base plate 101, an overlapping degree of a scope in which heat generated by the light-emitting chip 104 can be diffused is high, and heat concentration in the middle region is significant, resulting in a high probability that the light-emitting chip 104 is damaged by the heat. The heat generated by the light-emitting chip 104 in an edge region can be diffused to an outer region of the base plate 101 in which no light-emitting chip 104 is disposed such that a heat dissipation area of the light-emitting chip 104 is large. In addition, no heat is generated in the outer region such that the heat generated by the light-emitting chip can be conducted quickly. Therefore, for example, in the package 120, the quantity of light-emitting subassemblies 130 located in the middle region is less than the quantity of light-emitting subassemblies 130 located in the edge region. Correspondingly, in the collimating lens group 109, the quantity of collimating lenses T per row in the middle region is less than the quantity of collimating lenses T per row in the edge region. This can reduce the heat emitted by the light-emitting chip 104 in the middle region and heat received by the middle region of the base plate 101, to reduce the thermal density per unit area and increase the heat dissipation area of each light-emitting chip 104 in the middle region. In this way, the heat in the middle region is dissipated quickly, the probability that the light-emitting chip 104 in the middle region is damaged due to the heat is reduced, and the reliability of the laser 10 is improved.

The foregoing merely describes specific implementations of the present disclosure, but the protection scope of the present disclosure is not limited thereto. Any person skilled in the art can conceive modifications or replacements within the technical scope of the present disclosure, and these modifications or replacements shall fall within the protection scope of the present disclosure. Therefore, the protection scope of the present disclosure shall be subject to the protection scope of the claims.

What is claimed is:

1. A laser, comprising:
a base plate;
a frame disposed on the base plate and configured to form an accommodation space with the base plate;
a plurality of light-emitting subassemblies disposed on the base plate and in the accommodation space; and
a plurality of first conductive structures spaced apart at an end of the frame proximal to the base plate, wherein each of the first conductive structures comprises a substrate insulated from the base plate and a conductive layer disposed on a surface of the substrate distal to the base plate; and
a second conductive structure having one end electrically connected to the conductive layer and another end connected to at least one of the plurality of light-emitting subassemblies.

2. The laser according to claim 1, wherein both the plurality of first conductive structures and the frame are made of ceramic, and the plurality of first conductive structures and the frame are an integral structure.

3. The laser according to claim 1, wherein the plurality of first conductive structures are made of ceramic, the frame is made of metal and provided with a plurality of notches that are spaced apart at the end of the frame proximal to the base plate, and the plurality of first conductive structures are arranged in the plurality of notches in a one-to-one correspondence.

4. The laser according to claim 3, wherein a surface of the first conductive structure proximal to the base plate is flush with a surface of the frame proximal to the base plate.

5. The laser according to claim 3, wherein
the substrate comprises:
a first portion disposed on a side of the frame proximal to the plurality of light-emitting subassemblies;
a second portion disposed on a side of the frame distal to the plurality of light-emitting subassemblies; and
a third portion connected to and disposed between the first portion and the second portion, wherein the third portion is disposed in the notch;
the conductive layer comprises:
a first conductive layer disposed on a side of the first portion distal to the base plate; and
a second conductive layer disposed on a side of the second portion distal to the base plate; and
each of the first conductive structures further comprises a connection layer embedded inside the third portion, and the first conductive layer and the second conductive layer are electrically connected through the connection layer.

6. The laser according to claim 5, wherein a surface of the first portion distal to the base plate is flush with a surface of the second portion distal to the base plate.

7. The laser according to claim 3, wherein the plurality of notches are evenly distributed on two opposite sidewalls of the frame.

8. The laser according to claim 5, further comprising:
a printed circuit board (PCB) disposed on the side of the frame distal to the plurality of light-emitting subassemblies;
a first pad disposed on the base plate;
a second pad disposed on the PCB;
a connection line disposed on the base plate, and having one end electrically connected to the second conductive layer and another end electrically connected to the first pad; and
a connector disposed between the frame and the PCB, and having one end electrically connected to the first pad and another end electrically connected to the second pad.

9. The laser according to claim 8, wherein the connector comprises at least one bent portion.

10. The laser according to claim 5, wherein the plurality of light-emitting subassemblies comprise a first row of light-emitting subassemblies corresponding to a first row of first conductive layers, and the first row of first conductive layers comprises two said first conductive layers;
the laser further comprises an adapter disposed on the base plate, the laser corresponds to a second row of first conductive layers, the second row of first conductive layers comprises two said first conductive layers, and the adapter is configured to adapt the second conductive structure;
a part of the light-emitting subassemblies connected in series in the first row of light-emitting subassemblies have one end electrically connected to one said first conductive layer in the first row of first conductive layers and another end electrically connected to the adapter, and the adapter is electrically connected to one said first conductive layer in the second row of first conductive layers; and
other part of the light-emitting subassemblies connected in series in the first row of light-emitting subassemblies have one end electrically connected to another said first conductive layer in the first row of first conductive layers and another end electrically connected to the adapter, and the adapter is electrically connected to another said first conductive layer in the second row of first conductive layers.

11. The laser according to claim 10, wherein the adapter comprises two conductive regions insulated from each other, and the two conductive regions are disposed on a surface of the adapter distal to the base plate; and
one of the two conductive regions is electrically connected to the another end of the part of the light-emitting subassemblies connected in series in the first row of light-emitting subassemblies; and another of the two conductive regions is electrically connected to the another end of the other part of the light-emitting subassemblies connected in series in the first row of light-emitting subassemblies.

12. The laser according to claim 1, wherein a side of the frame distal to the base plate is provided with an opening, the plurality of light-emitting subassemblies are configured to emit laser light; and the laser further comprises:
a light-transmitting layer disposed on a side of the frame on which the opening is located;
a cover plate comprising an inner edge region and an outer edge region, wherein the outer edge region is fastened to a surface of the frame distal to the base plate, and the inner edge region is fastened to an edge of the light-transmitting layer.

13. The laser according to claim 12, further comprising:
a collimating lens group disposed on a side of the light-transmitting layer distal to the base plate and comprising a plurality of collimating lenses, wherein at least one of the plurality of collimating lenses is configured to decrease a divergence angle of incident laser light and make a decrease in a divergence angle of the laser light on a slow axis less than a decrease in a divergence angle of the laser light on a fast axis.

14. The laser according to claim 13, wherein each of the collimating lenses comprises:
a first surface, wherein the laser light emitted by the light-emitting subassembly is incident to the collimating lens through the first surface, and the first surface is configured to increase the divergence angle of the incident laser light on the slow axis; and
a second surface, wherein the laser light emitted by the light-emitting subassembly is emergent from the collimating lens through the second surface, and the second surface is configured to decrease the divergence angles of the incident laser light on the fast axis and the slow axis.

15. The laser according to claim 14, wherein there is one of:
the first surface comprises a concave arc surface having a radius of curvature in a first direction less than a radius of curvature in a second direction, the first direction being perpendicular to the second direction;
the first surface comprises a concave cylindrical surface with a straight generatrix being parallel to a second direction;
the second surface comprises a convex arc surface with a same curvature in a first direction and a second direction, the first direction being perpendicular to the second direction;
the second surface comprises a convex arc surface, the convex arc surface is a free-form surface, and the convex arc surface has a radius of curvature in a first direction greater than a radius of curvature in a second direction, the first direction being perpendicular to the second direction;
the first surface comprises a concave arc surface, the second surface comprises a convex arc surface, and a radius of curvature of the concave arc surface is greater than a radius of curvature of the convex arc surface; or
the first surface is a flat surface, the second surface comprises a convex arc surface, the convex arc surface is a free-form surface, and the convex arc surface has a radius of curvature in a first direction greater than a radius of curvature in a second direction, the first direction being perpendicular to the second direction.

16. The laser according to claim 1, further comprising:
a collimating lens group disposed on a side of the light-transmitting layer distal to the base plate and comprising a plurality of collimating lenses, wherein the plurality of collimating lenses are arranged in a plurality of rows in a row direction and a plurality of columns in a column direction; and for at least one of the plurality of collimating lenses, a maximum length in the column direction is greater than a maximum length in the row direction, and widths of two end portions are both less than a width of a middle portion in the column direction; wherein
two adjacent rows of collimating lenses in the plurality of collimating lenses are staggered; and in the two adjacent rows of collimating lenses, an end portion of a collimating lens in one row of collimating lenses proximal to another row of collimating lenses is at least partially located between two end portions of two adjacent collimating lenses in the another row of collimating lenses.

17. The laser according to claim 16, wherein there is one of:
an orthographic projection of the collimating lens on the base plate is a hexagon, and the hexagon is symmetrical about an axis of symmetry parallel to the column direction; or
an orthographic projection of the collimating lens on the base plate is an ellipse, and a major axis of the ellipse is parallel to the column direction.

18. The laser according to claim 16, in three adjacent rows of collimating lenses, an orthographic projection of each collimating lens in the two rows of collimating lenses located at both ends on the base plate is an ellipse, the row of collimating lenses in the middle comprises a first-type collimating lens, and an orthographic projection of the first-type collimating lens on the base plate is in a target shape; and the target shape is enclosed by six edges, the six edges comprise two parallel and opposite straight edges, two arc edges respectively connected to one end of the two straight edges, and two arc edges respectively connected to another end of the two straight edges, and the arc edges are recessed toward inside of the target shape.

19. The laser according to claim 16, wherein the collimating lens comprises a second-type collimating lens, an orthographic projection of the second-type collimating lens on the base plate is in an auxiliary shape, the second-type collimating lens is located at an edge of the collimating lens group, and an edge of the second-type collimating lens that is not adjacent to other collimating lenses is a straight edge.

20. The laser according to claim 16, wherein in the plurality of collimating lenses, any two adjacent collimating lenses in adjacent rows are in contact with each other; or
any two adjacent collimating lenses in a same row are in contact with each other;
in the collimating lens group, two rows of collimating lenses located on both sides of and adjacent to any row of collimating lenses are aligned in the column direction.
